(19) United States
(12) Patent Application Publication
(10) Pub. No.: US 2004/0063295 A1
(43) Pub. Date: Apr. 1, 2004

(54) One-mask process flow for simultaneously constructing a capacitor and a thin film resistor

(75) Inventors: Stephen T. Chambers, Portland, OR (US); Rick Davis, Beaverton, OR (US); Philip Yashar, Hillsboro, OR (US)

Correspondence Address: Pillsbury Winthrop LLP, Intellectual Property Group, Suite 2800, 725 South Figueroa Street, Los Angeles, CA, 90017-5406, US

(73) Assignee: Intel Corporation, Santa Clara, CA (US)

(21) Appl. No.: 10/261,226

(22) Filed: Sep. 30, 2002

(51) Int. Cl. H01L 21/8234; H01L 21/8244; H01L 21/20

(52) U.S. Cl. 438/382; 438/384; 438/396

(57) ABSTRACT

A method includes forming a first damascene interconnect layer in a first dielectric. A first dielectric film is deposited on the first dielectric and on the first damascene interconnect layer. A conductor layer is deposited on the first dielectric film. The conductor layer is patterned, via a single mask, to form a first conductor and a second conductor. The first damascene interconnect level, the first dielectric film, and the first conductor form a capacitor and the second conductor forms a resistor.

### BACKGROUND

1. Technical Field

This invention relates to the field of semiconductor manufacturing, and more specifically, to a method utilizing a single mask to simultaneously construct a capacitor and a thin film resistor.

b 2. Description of the Related Arts

There are current systems and methods in the art to form a capacitor and a resistor. Such methods are complex and often require use of two or three masks. Such methods are utilized to form the capacitor and the resistor on a semiconductor wafer.

Typically, a first mask is used to create an opening in a dielectric film above an existing metal interconnect pattern. A metal film, to be used as the bottom electrode of the capacitor and a thin film resistor is then deposited, followed by deposition of a dielectric film to be used as the capacitor insulator. A second mask is used to pattern this dielectric and metal film. Next another metal film is deposited that will be patterned with a third mask to form the top electrode of the capacitor.

Accordingly, current systems and method of forming capacitors and resistors are inefficient because multiple masks are utilized during the process. The use of multiple masks makes the entire process complex, increasing the chances of an error occurring, decreasing yield, slowing the process, and increasing costs.

### BRIEF DESCRIPTION OF THE DRAWINGS

FIGS. 1A-I are representational cross-sections of a capacitor and a thin film resistor being fabricated simultaneously through use of a single mask according to an embodiment of the invention;

FIG. 2 illustrates a method to simultaneously construct a capacitor and a thin film resistor according to an embodiment of the invention; and

FIG. 3 illustrates a semiconductor fabrication device to simultaneously construct a capacitor and a thin film resistor according to an embodiment of the invention.

### DETAILED DESCRIPTION

An embodiment of the invention may be utilized to simultaneously form a capacitor and a thin film resistor through the use of a single mask. Such use of a single mask results in the construction of the capacitor and the thin film resistor via a method involving minimal complexity.

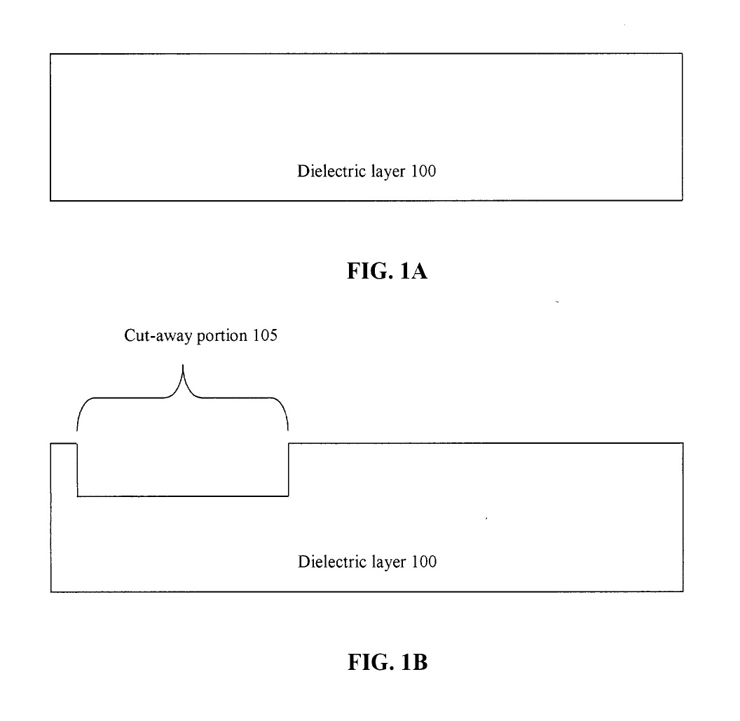

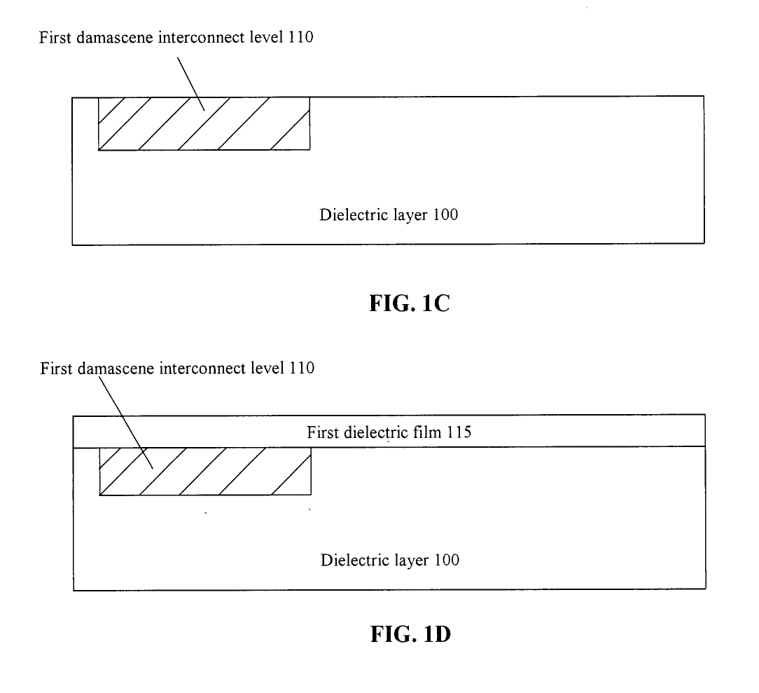

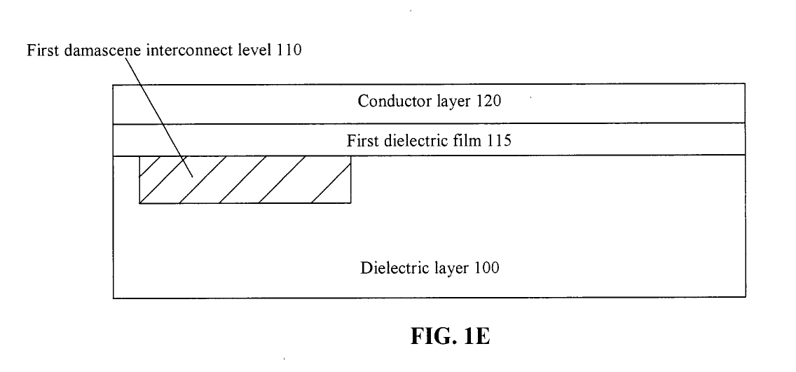

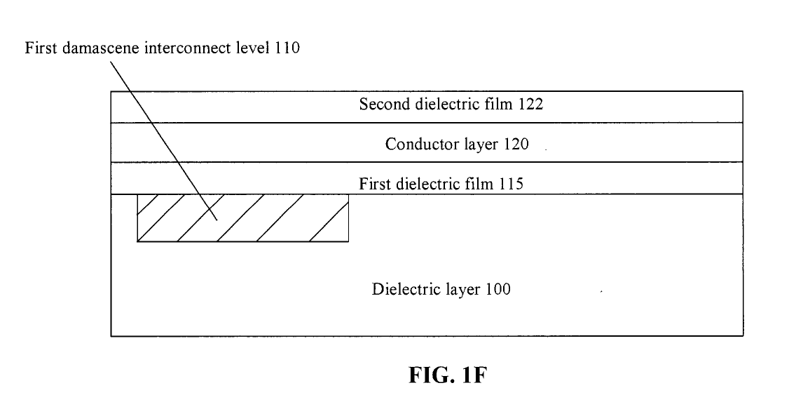

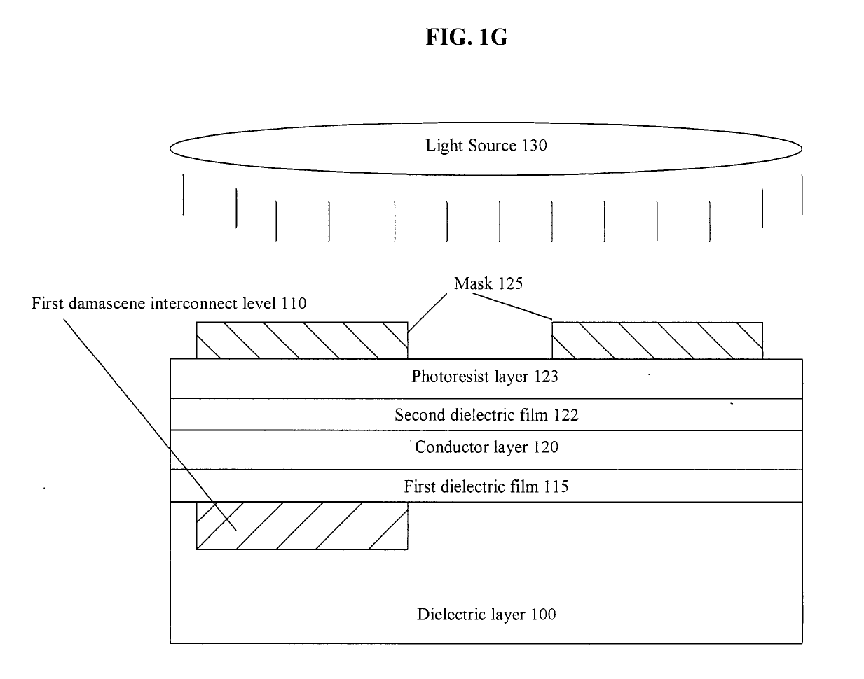

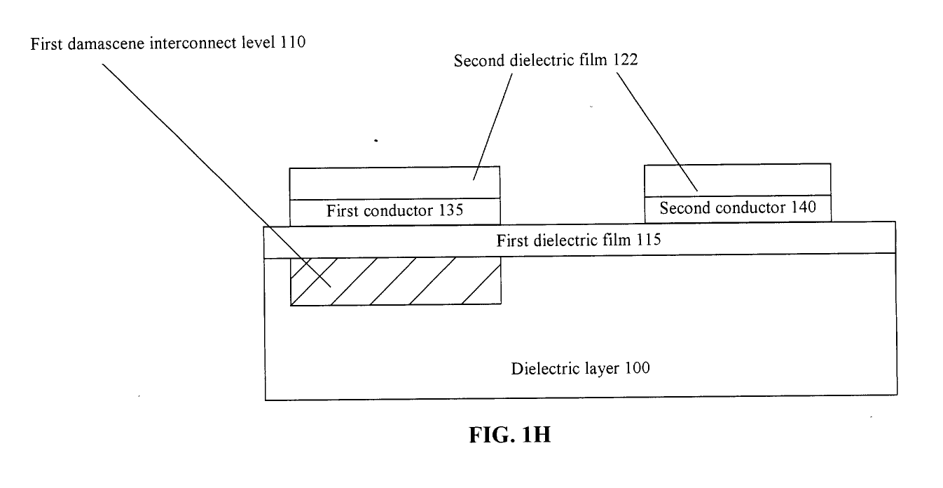

FIG. 1A illustrates a dielectric layer 100. The dielectric layer 100 may be deposited on a silicon wafer, or on any other suitable surface, in a fabrication lab, for example. The dielectric layer 100 may be formed of silicon dioxide (SiO₂), or any other suitable dielectric material.

FIG. 1B illustrates the dielectric layer 100 after a portion (i.e., the “cut-away portion 105”) of the dielectric layer 100 has been removed. The cut-away portion 105 may be removed via an etching process. The etching process may utilize plasma etching techniques. The cut-away portion 105 may resemble a trench, for example, when removed. The portion of the dielectric layer 100 is removed to create the cut-away portion 105 so that the cut-away portion 105 may be filled with a metal or other material as described below with respect to FIG. 1C.

FIG. 1C illustrates the dielectric layer 100 having a first damascene interconnect level 110 in place of the cut-away portion 105. The first damascene interconnect level 110 may be formed in the cut-away portion 105 of the dielectric 100 by a damascene process. According to the damascene process, a trench (i.e., the cut-away portion 105) may be cut in the dielectric layer 100, and may then be filled with a metal such as copper, to form the first damascene interconnect level 110. Copper may be utilized to fill the first damascene interconnect level 110 because it is resistant to electro-migration and has a low resistivity.

FIG. 1D illustrates the dielectric layer 100 having a first damascene interconnect level 110 after a dielectric film 115 has been deposited thereon. The dielectric film 115 may be formed by Plasma Enhanced Chemical Vapor Deposition (PECVD) of SiN (silicon nitride). PECVD is a technique of depositing a film (e.g., the silicon nitride) onto the dielectric layer 100 and the first damascene interconnect level 110. PECVD may be performed with standard semiconductor equipment. The use of plasma in the PECVD process allows lower deposition temperatures to be utilized, because some of the energy for the deposition comes from the plasma instead of solely from thermal energy.

The dielectric film 115 may be the first layer utilized to simultaneously form a capacitor and a thin film resistor according to an embodiment of the invention.

FIG. 1E illustrates a dielectric layer 100 having first damascene interconnect level 110, a dielectric film 115, after a conductor layer 120 has been deposited thereon. The conductor layer 120 may be deposited directly on top of the first dielectric film 115. The conductor layer 120 may be deposited by a sputter deposition technique. The conductor layer 120 may be utilized to form the top electrode of an capacitor and a resistor, for example. The conductor layer 120 may be formed of a conductive material such as tantalum (Ta) or tantalum nitride (TaN). In other embodiments, the conductor layer 120 may be formed of a non-metal conductive material such as polysilicon.

FIG. 1F illustrates the dielectric layer 100 having the first damascene interconnect level 110, the first dielectric film 115, and the conductor layer 120, after a second dielectric film 122 has been deposited thereon. The second dielectric film 122 may be deposited on top of the conductor layer 120. The second dielectric film 122 may be silicon nitride, for example. The second dielectric film 122 may be utilized to protect the conductor layer 120 during a patterning process discussed below with respect to FIG. 1G. In some embodiments, the second dielectric film 122 may be very thin and may be deposited when the conductor layer 120 is deposited by the sputter deposition process. In other embodiments, the second dielectric film 122 may not be necessary.

FIG. 1G illustrates the dielectric layer 100 having the first damascene interconnect level 110, the first dielectric film 115, the conductor layer 120, and the second dielectric film 122, after addition of a photoresist layer 123 patterned with a mask 125 and light source 130. The light source 130 may shine light onto the photoresist layer 123, causing the exposed portions of the photoresist layer 123 to chemically change. The wafer may then be immersed in a chemical, which dissolves either the exposed or unexposed portion of the photoresist layer 123. The pattern of the photoresist layer 123 is then etched into the second dielectric film 122 and the conductor layer 120. The photoresist layer 123 is then removed from the wafer. Accordingly, the conductor layer 120 and the second dielectric film 122 may be patterned per a standard patterning process and plasma etch.

FIG. 1H illustrates the dielectric layer 100 having the first damascene interconnect level 110, and the first dielectric film 115, after the conductor layer 120 has been patterned to form a first conductor 135 and a second conductor 140. The second dielectric film 122 may remain above the first conductor 135 and above the second conductor 140. Accordingly, after the second dielectric film 122 and the conductor layer 120 have been patterned, the capacitor and the thin film resistor have been formed. The first conductor 135, the first dielectric film 115, and the first damascene interconnect level 110 may form the capacitor. The second conductor 140 may form the thin film resistor. In some embodiments, the patterned capacitor may be coupled to the thin film resistor. In other embodiments, the capacitor and the thin film resistor may not be coupled.

Accordingly, from the time that the first dielectric film 115 was deposited until the conductor layer 120 and the second dielectric film 122 were deposited and patterned, only one mask 125 was utilized to form the capacitor and the thin film resistor. If additional layers are to be deposited onto the wafer, an upper damascene interconnect level may be formed on top of the second dielectric film 122 and the first conductor 135 and the second conductor 140.

FIG. 1I illustrates an upper damascene interconnect level 155 formed on top of a capacitor and a thin film resistor according to an embodiment of the invention. To form the upper damascene interconnect level 155, a third dielectric film 145 may be deposited on top of the second dielectric film 122 and the first dielectric film 110. The third dielectric film 145 may be formed of silicon nitride, for example. Next, a second dielectric layer 150 may be deposited on top of the third dielectric film 145. The second dielectric layer 150 may be silicon dioxide, for example. Then, by using plasma-etching techniques, cut-away portions may be removed from second dielectric layer 150 and the resulting trenches may be subsequently filled with the third conductor 160, which may connect to first conductor 135 (i.e., part of the capacitor) and the second conductor 140 (i.e., the thin film resistor).

FIG. 2 illustrates method for simultaneously fabricating a capacitor and a thin film resistor according to an embodiment of the invention. First, a dielectric 100 may be deposited 200 on a surface, such as a surface of a semiconductor wafer. Next, a damascene interconnect level 110 may be formed 205 by a damascene process. The damascene process may entail etching a trench in the dielectric 100, and filling the trench with a metal such as copper. A first dielectric film 115 may then be deposited 210 on the first damascene interconnect layer 110 and the dielectric 100. Next, a conductor layer 120 may be deposited 215 on the first dielectric film 115. A second dielectric film 122 may then be deposited 220 on top of the conductor layer 120. In some embodiments, the second dielectric film 122 may not be needed. The conductor layer 120 and the second dielectric film 122 may then be patterned 225. A mask 125 along with photoresist layer 123 and a light source 130 may be utilized in the patterning process. After the photoresist patterning process, the conductor layer 120 may be patterned into a first conductor 135 and a second conductor 140. The first conductor 135 may form part of a capacitor, and the second conductor 140 may form part of a thin film resistor. Finally, an upper damascene level 155 may be created 230 above the second dielectric film 122, the first 135 and second 140 conductors, and the first dielectric film 115.

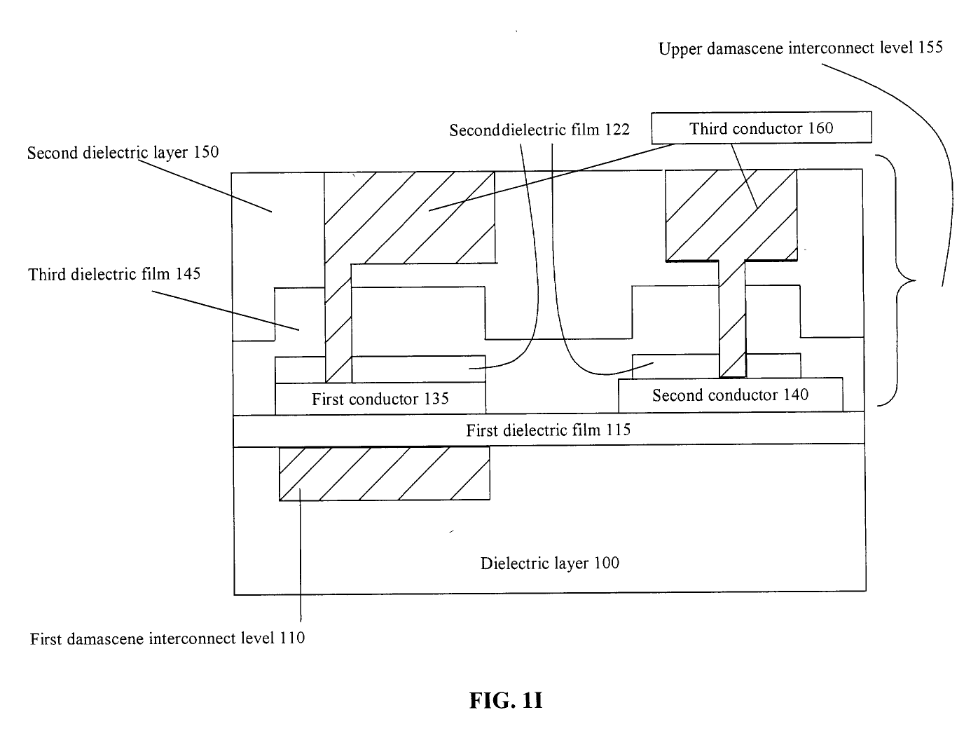

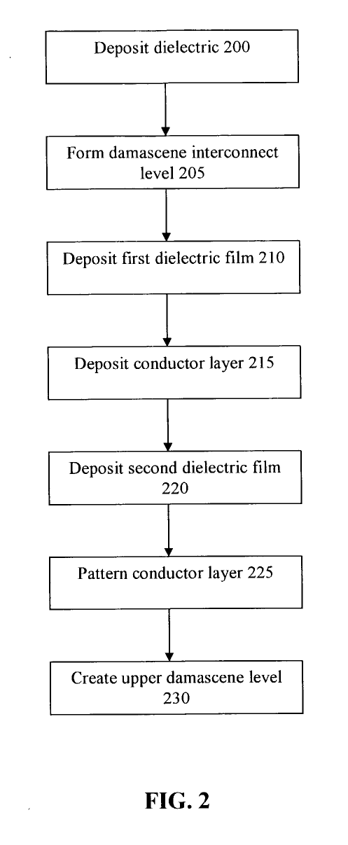

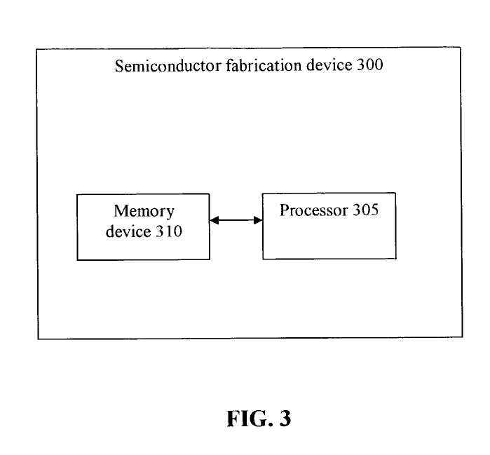

FIG. 3 illustrates a semiconductor fabrication device 300 to simultaneously construct a capacitor and a thin film resistor according to an embodiment of the invention. The semiconductor fabrication device 300 may be a standard fabrication device. The semiconductor fabrication device 300 may include a processor 305 and a memory device 310. The processor may be utilized to execute instructions stored in the memory device 310, to cause the semiconductor fabrication device 300 to simultaneously form the capacitor and the thin film resistor through use of a single mask.

The constructed capacitor described above may be a Metal-Insulator-Metal (MIM) capacitor, having tantalum or tantalum nitride as the top metal layer. In other embodiments, the top layer of the capacitor may be a non-metal conductor such as polysilicon.

While the description above refers to particular embodiments of the present invention, it will be understood that many modifications may be made without departing from the spirit thereof. The accompanying claims are intended to cover such modifications as would fall within the true scope and spirit of the present invention. The presently disclosed embodiments are therefore to be considered in all respects as illustrative and not restrictive, the scope of the invention being indicated by the appended claims, rather than the foregoing description, and all changes which come within the meaning and range of equivalency of the claims are therefore intended to be embraced therein.

What is claimed is:

1. A method, comprising:
forming a first damascene interconnect level in a first dielectric layer;
depositing a first dielectric film on the first dielectric and on the first damascene interconnect layer;
depositing a conductor layer on the first dielectric film; and
patterning the conductor layer, via a single mask, to form a first conductor and a second conductor,
wherein the first damascene interconnect level, the first dielectric film, and the first conductor form a capacitor and the second conductor forms a resistor.

2. The method of claim 1, wherein the first dielectric layer is silicon dioxide.

3. The method of claim 1, wherein the first dielectric film is Plasma Enhanced Chemical Vapor Deposited (PECVD) silicon nitride.

4. The method of claim 1, wherein the conductor layer includes tantalum.

5. The method of claim 1, wherein the conductor layer includes polysilicon.

6. The method of claim 1, wherein a second dielectric layer is deposited on the conductor layer before the patterning of the conductive layer.

7. The method of claim 1, further including depositing the first dielectric layer on a surface.

8. The method of claim 7, wherein the surface is a substrate of a wafer.

9. The method of claim 1, further including filling the damascene interconnect level with copper.

10. A method, comprising:
depositing a first dielectric film on a first dielectric and on a first damascene interconnect level;
depositing a conductor layer on the first dielectric film;
patterning the conductor layer, via a single mask, to form a first conductor and a second conductor,
wherein the first damascene interconnect level, the first dielectric film, and the first conductor form a capacitor and the second conductor forms a resistor; and
depositing a second damascene interconnect level on the conductor layer after the patterning.

11. The method of claim 10, further including forming the first damascene interconnect level in the first dielectric layer.

12. The method of claim 10, wherein the first dielectric layer is silicon dioxide.

13. The method of claim 10, wherein the first dielectric film is Plasma Enhanced Chemical Vapor Deposited (PECVD) silicon nitride.

14. The method of claim 10, wherein the conductor layer includes tantalum.

15. The method of claim 10, wherein the conductor layer includes polysilicon.

16. The method of claim 10, wherein a second dielectric layer is deposited on the conductor layer before the patterning of the conductive layer.

17. The method of claim 10, further including depositing the first dielectric layer on a surface.

18. The method of claim 17, wherein the surface is a substrate of a wafer.

19. The method of claim 10, further including filling the damascene interconnect level with copper.

20. An article comprising:
a storage medium having stored thereon first instructions that when executed by a machine result in the following:
forming a first damascene interconnect level in a first dielectric layer;
depositing a first dielectric film on the first dielectric and on the first damascene interconnect layer;
depositing a conductor layer on the first dielectric film; and
patterning the conductor layer, via a single mask, to form a first conductor and a second conductor,
wherein the first damascene interconnect level, the first dielectric film, and the first conductor form a capacitor and the second conductor forms a resistor.

21. The article of claim 20, wherein the first dielectric layer is silicon dioxide.

22. The article of claim 20, wherein the first dielectric film is Plasma Enhanced Chemical Vapor Deposited (PECVD) silicon nitride.

23. The article of claim 20, wherein the conductor layer includes tantalum.

24. The article of claim 20, wherein the conductor layer includes polysilicon.

25. The article of claim 20, wherein the instructions further result in a second dielectric layer being deposited on the conductor layer before the patterning of the conductive layer.

26. The article of claim 20, further including depositing the first dielectric layer on a surface.

27. The article of claim 26, wherein the surface is a substrate of a wafer.

28. The article of claim 20, wherein the instructions further result in filling the damascene interconnect level with copper.
